(19) United States
(12) Patent Application Publication
(10) Pub. No.: US 2008/0217517 A1
(43) Pub. Date: Sep. 11, 2008

(54) Monolithic ambient light detector

(76) Inventor: Tzu-Chiang Hsieh, Fremont, CA (US)

Correspondence Address: TREX ENTERPRISES CORP., 10455 PACIFIC COURT, SAN DIEGO, CA, 92121, US

(21) Appl. No.: 12/008,585

(22) Filed: Jan. 11, 2008

Related U.S. Application Data
(60) Provisional application No. 60/879,881, filed on Jan. 11, 2007.

(51) Int. Cl. H03F 3/08

(52) U.S. Cl. 250/214 A

(57) ABSTRACT

A monolithic ambient light detector. The detector includes on a single CMOS integrated circuit a photodiode matching almost perfectly the spectral response of the human eye and CMOS integrated circuitry for providing output digital signals indicating ambient light levels for controlling light intensity of electronic display monitors. The entire detector is fabricated on a single CMOS integrated circuit chip.

The present invention relates to detectors and in particular to ambient light detectors. This application claims the benefit of provisional patent application Ser. No. 60/879,881 filed Jan. 11, 2007.

### BACKGROUND OF THE INVENTION

All ambient light detectors used to control the on/off or dimming of householders' lightings available in the market place have their primary spectral response in the red into near-IR region. They can do the job, but they are far from desirable since they do not reflect the ambient lightness based upon human vision. But, for the applications, customers usually lower their expectation on the performance without major rejections.

Nowadays, there are more and more mobile devices equipped with display screen for serious image or video or even TV viewing. Those displays, either using passive LCD or TFT-LCD or Organic LED, have one thing in common—a quite limited dynamic range. As a matter of fact, even the high end flat TV's, using TFT-LCD or Plasma or Rear-projection light valves, suffer the same weakness—limited dynamic range. This may be a reason why the vendors prefer to show off their latest plat TV's in a dark room like a movie theater. As a result of it, these displays need to dynamically adjust the contrast ratio according to the human's perception on the ambient levels so human users can enjoy the contents. It is these new applications that in many cases will justify ambient light control to mimic human vision. At the end of the day, the contrast adjustment is to please human vision so human users can focus on the display contents not to be distracted to find a darker room to overcome the limitations of the display devices.

What is needed is an ambient light detector that can utilized to automatically control the brightness of video displays as needed to provide the most desirable brightness for comfortable enjoyment of the video display.

### SUMMARY OF THE INVENTION

The present invention provides a monolithic ambient light detector. The detector includes on a single CMOS integrated circuit a photodiode matching almost perfectly the spectral response of the human eye and CMOS integrated circuitry for providing output digital signals indicating ambient light levels for controlling light intensity of electronic display monitors. The entire detector is fabricated on a single CMOS integrated circuit chip.

### BRIEF DESCRIPTION OF THE DRAWINGS

FIG. 1 shows a spectral response of a preferred embodiment of the present invention.

FIG. 2 is a block diagram of a preferred embodiment of the present invention.

FIG. 3 is a block diagram showing circuitry of a preferred embodiment.

### DETAILED DESCRIPTION OF PREFERRED EMBODIMENTS

### An a-Si/CMOS Integrated Process

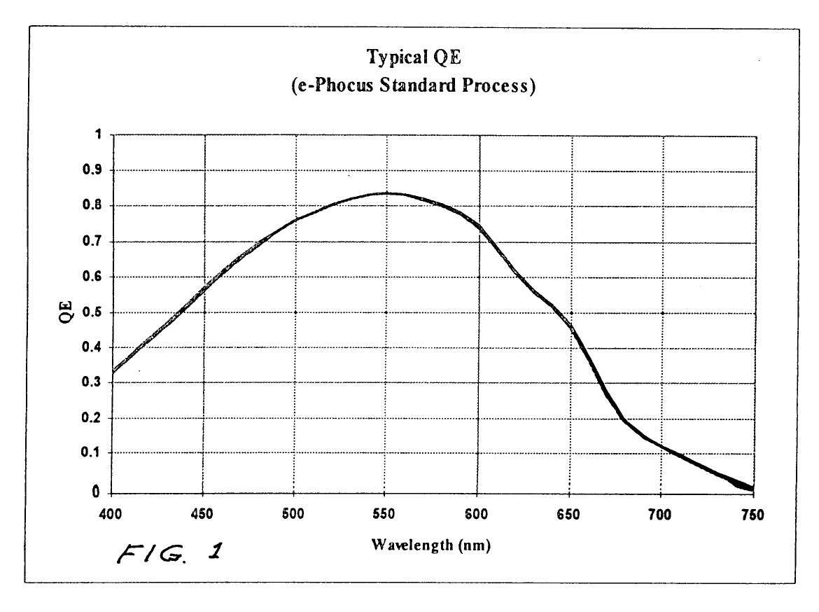

Applicant and his associates have developed a hydrogenated a-Si p-i-n diode that has a spectral response with a peak at 550 nm and of a range from 400 nm to 700 nm. It matches human vision in luminance extremely well, far better than any other sensing technology as shown in FIG. 1.

### First Preferred Embodiment

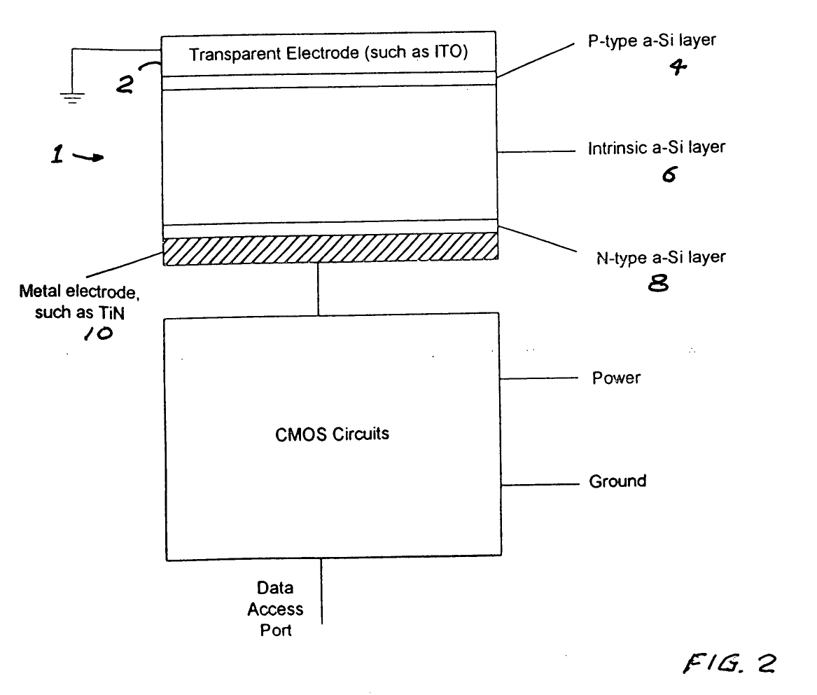

A first preferred embodiment of the present invention is a monolithic ambient light detector. In this embodiment, an a-Si p-i-n photodiode of about 1 mm×1 mm is fabricated on top of a CMOS signal detection circuit as shown in FIG. 2. The photodiode 1 consists of:
a. A transparent surface electrode 2, such as ITO
b. The photodiode is made of
   i. P-type Hydrogenated a-Si layer 4
   ii. Intrinsic Hydrogenated a-Si layer 6
   iii. N-type Hydrogenated a-Si layer 8
c. A bottom metal electrode 10, such as TiN (as used in our POAP sensor), to serve as the contact to other part of the CMOS circuits

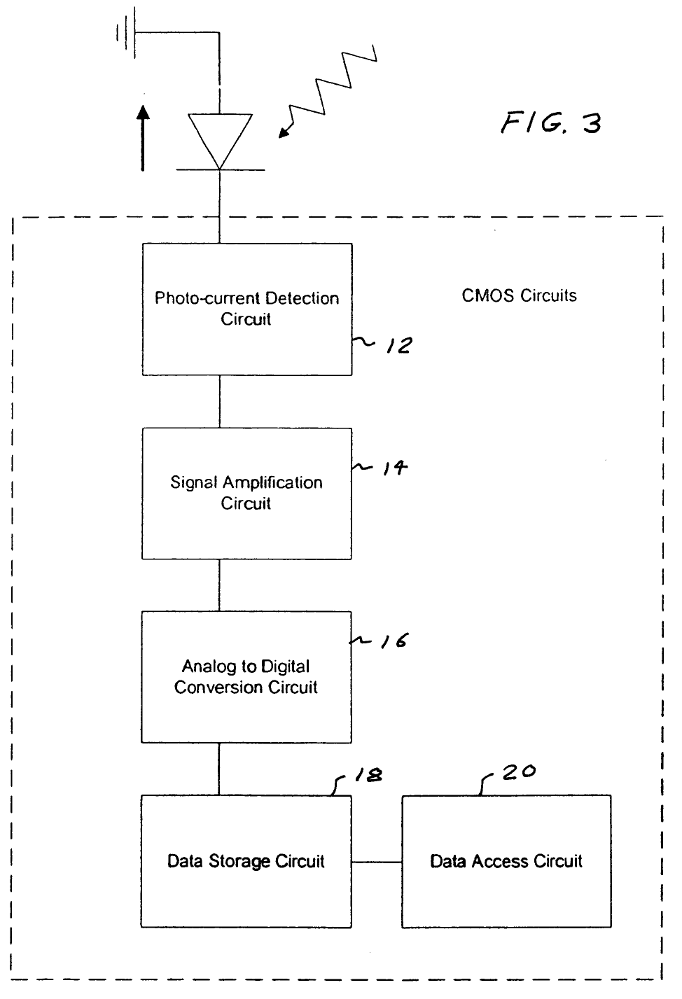

CMOS circuitry is position below the bottom metal layer as shown in FIG. 2. A block diagram of the circuitry is shown in FIG. 3. It consists of:
1. A photo-current detection circuit 12 to convert the photo-current generated in the photodiode into electrical signal, either in current or voltage form, to be used in the down-stream circuits.
2. A signal amplification circuit 14 to condition the signal out of the photo-current detection circuit before the analog-to-digital conversion circuit. One can design either linear amplifier or other non-linear amplifier such as logarithmic amplifier.
3. An analog-to-digital circuit 16.
4. A data storage circuit 18 to store the data converted from the analog-to-digital circuit represent the light being detected by the photodiode, in digital form.
5. A data access circuit 20 designed to allow other circuits to retrieve the light information stored in the data storage circuit 18.

### Advantages of the Preferred Embodiment

Applicant's a-Si based photodiode mimics human luminous spectral response. It does not require any band-pass, long-pass or short-pass filters to shape its spectral response to mimic human luminous response. This would provide an intrinsic advantage over c-Si based photodiode integrated with other CMOS circuits in the same silicon substrate. Applicant's invention permits the design of versatile CMOS circuits in conjunction with the hydrogenated a-Si photodiode in a monolithic format. In addition Applicant's monolithic ambient light detector has intrinsic cost, weight and compactness advantage over other ambient light detector requiring multiple discrete components.

Although the present invention has been described in terms of a specific preferred embodiment readers should understand that many changes and alteration could be made without departing from the true spirit of the invention. For example although as stated above there is excellent matching of the spectral response of the preferred embodiment with human eyes, some improvements could be provided with the addition of a simple green filter. Therefore the scope of the invention should be determined by the appended claims.

What is claimed is:

1. A monolithic ambient light detector comprising:
A) an a-Si/CMOS photodiode matching almost perfectly the spectral response of the human eye and
B) CMOS integrated circuitry fabricated below said photodiode on a single substrate and adapted to provide output digital signals indicating ambient light levels for controlling light intensity of electronic display monitors.

2. The detector as in claim 1 wherein said photodiode comprises a ITO surface layer, a p-type a-Si top layer, an intrinsic a-Si layer and a p-type a-Si bottom layer and a metal electrode.

3. The detector as in claim 1 wherein said CMOS integrated circuitry comprises a photodiode detection circuit, a signal amplification circuit, an analog to digital circuit and a data storage circuit and a data access circuit.
